(19) United States
(12) Patent Application Publication
(10) Pub. No.: US 2026/0318490 A1
(43) Pub. Date: Oct. 15, 2026

(54) LED STRIP LIGHTING DEVICES AND METHODS

(71) Applicant: SIGNIFY HOLDING B.V., EINDHOVEN (NL)

(72) Inventors: PHILIP WINTERS, DENVER, CO (US); ADAM MOORE FOY, PARKER, CO (US); KENNETH CHARLES FRATZKE, ARVADA, CO (US); JAMES RICHARD EISELE, LITTLETON, CO (US); NEIL THOMAS HARDWICK, LOUISVILLE, CO (US); MELISA ALTAMIRANO-RUELAS, DENVER, CO (US); ALEXANDER JAMES ROSS, AURORA, CO (US)

(21) Appl. No.: 19/112,824

(22) PCT Filed: Sep. 21, 2023
(86) PCT No.: PCT/EP2023/076123

§ 371 Date: Mar. 18, 2025

Related U.S. Application Data
(60) Provisional application No. 63/409,466, filed on Sep. 23, 2022.

(30) Foreign Application Priority Data
Oct. 3, 2022 (EP) 22199327.2

(51) Int. Cl. F21S 4/28; F21S 4/22; F21V 7/00

(52) U.S. Cl. CPC F21S 4/28; F21S 4/22; F21V 7/00

(57) ABSTRACT

A lighting device (100) including a light emitting diode (LED) spinal component (102) and a circuit board strip (120) is disclosed. The LED spinal component (102) includes an LED (104) disposed on a first circuit board (106) including first electrical conductors (108) coupled to the LED. The circuit board strip (120) includes second electrical conductors (122) coupled to the first electrical conductors, where the material composing the 5 strip is more flexible than the first circuit board, and where the LED spinal component is attached at a portion (124) of a surface (126) of the strip such that a primary light emitting surface (105) of the LED spinal component is at a perpendicular or oblique angle to the portion of the surface of the strip at which the LED spinal component is attached.

### TECHNICAL FIELD

The present invention is directed generally to light-emitting diode (LED) strip lighting and, more particularly, to LED strip lighting devices, systems and methods.

### BACKGROUND

Flexible LED strip lighting, commonly referred to as LED tape, is typically composed of LEDs disposed on a flexible substrate and is employed to trace non-linear surfaces and provide aesthetic or general illumination thereon. The LEDs of LED tape are mounted on the main surface of the tape so that a hemispherical lighting pattern is provided at the surface. However, such a hemispherical light output is not always ideal for certain applications, especially where lateral light emitting patterns are desired. To implement such patterns with LED tape, side-emitting LEDs can be utilized. With side-emitting LEDs, light is emitted by the diode through the small surface area of a side face of its light emitting layer. Alternatively, lateral light emitting patterns can be implemented on LED tape by employing a reflector with the hemispherical lighting of a typical LED tape arrangement. Here, the light from the hemispherical illumination pattern can be reflected off of an angled white surface incorporated into the product's sheath.

### SUMMARY

A problem with the use of side-emitting LEDs or a reflector to implement lateral light emitting patterns is that they typically have diminished optical quality. For example, due to limited light-emitting surface area, side-emitting LEDs generate a wall-grazing effect, as opposed to a wall-washing effect which may be preferred. In turn, the use of a reflector to provide a lateral light emitting pattern reduces the brightness of the device by the amount of light absorbed by the surface of the reflector.

In contrast to these methods, embodiments of the present application can provide a lateral light emitting pattern that has a wall-washing effect without diminished brightness. In addition, the configurations disclosed herein can provide space for additional electrical components, and can improve the structural integrity of optics provided on LED devices. These benefits can be achieved by employing circuit boards with different flexibilities. For example, a flexible circuit board strip can be utilized with a rigid circuit board that acts as a spinal component. Here, the rigid circuit board supports an LED and is mounted to the flexible circuit board at a perpendicular or oblique angle. Thus, in this way, for example, the device can provide a wall-washing effect with a high intensity, while at the same time permit the addition of electrical components at the back side of the rigid circuit board without affecting the flexibility of the underlying strip. In addition, in contrast to traditionally mounted LEDs on LED tape, the structural integrity of any optical elements can be significantly improved, as the configurations disclosed herein can substantially reduce the risk of delamination of such optical elements when the underlying strip is flexed.

In accordance with one exemplary aspect of the present application, a lighting device includes a light emitting diode spinal component and a circuit board strip. The LED spinal component includes an LED disposed on a first circuit board including first electrical conductors coupled to the LED. The circuit board strip includes second electrical conductors coupled to the first electrical conductors, where the material composing the strip is more flexible than the first circuit board, and where the LED spinal component is attached at a portion of a surface of the strip such that a primary light emitting surface of the LED spinal component is at a perpendicular or oblique angle to the portion of the surface of the strip at which the LED spinal component is attached.

According to one embodiment, the flexibility of the material composing the strip is such that a first end of a six-inch long strip of the material is bendable 360 degrees back onto a second, opposing end of the six-inch long strip without incurring breakage. In turn, the material composing the first circuit board is such that a first end of a six-inch long piece of the material composing the first circuit board is unbendable 360 degrees back onto a second, opposing end of the six-inch long piece.

In an additional exemplary embodiment, an optical element is disposed on the LED and is configured to form an optical effect from light emitted by the LED. In one version of this embodiment, the first circuit board provides the optical element with a degree of structural integrity that is greater than a structural integrity of the optical element if disposed on the circuit board strip.

In accordance with an exemplary embodiment, the first circuit board is a rigid printed circuit board and the strip is a flex printed circuit board.

Further, in an embodiment, the LED spinal component is included in a plurality of LED spinal components attached to respective portions of the surface of the strip such that primary light emitting surfaces of the plurality of LED spinal components are at a perpendicular or oblique angle to the respective portions of the surface of the strip. In one version of this embodiment, each LED spinal component of the plurality is free standing with respect to each other LED spinal component of the plurality.

In another version of this embodiment, the strip is a first strip, where the lighting device further comprises a second strip that is perpendicularly or obliquely attached to the first strip and where the plurality of LED spinal components are disposed on the second strip. The material composing the second strip can be more flexible than the first circuit board. In addition, the second strip may be a reflector.

According to an exemplary embodiment, the LED spinal component includes a coupler having a first surface and a second surface that is at a perpendicular or oblique angle to the first surface. Here, the first circuit board is disposed on the first surface, and the portion of the surface of the strip is disposed on the second surface.

In accordance with another aspect, a method for producing a lighting device comprises forming an LED spinal component by fashioning an LED on a first circuit board such that first electrical conductors of the first circuit board are coupled to the LED. In addition, the method includes attaching the LED spinal component to a circuit board strip such that second electrical conductors of the strip are coupled to the first electrical conductors, where the material composing the strip is more flexible than the first circuit board and where the LED spinal component is attached at a portion of a surface of the strip such that a primary light emitting surface of the LED spinal component is at a perpendicular or oblique angle to the portion of the surface of the strip at which the LED spinal component is attached.

In accordance with one embodiment, the attaching comprises soldering the LED spinal component to the surface of the strip. In an additional embodiment, the fashioning comprises attaching the LED on to the first circuit board. In an alternative embodiment, the fashioning comprises constructing the LED on the first circuit board.

As used herein for purposes of the present disclosure, the term “LED” should be understood to include any electroluminescent diode or other type of carrier injection/junction-based system that is capable of generating radiation in response to an electric signal. Thus, the term LED includes, but is not limited to, various semiconductor-based structures that emit light in response to current, light emitting polymers, organic light emitting diodes (OLEDs), electroluminescent strips, and the like. In particular, the term LED refers to light emitting diodes of all types (including semi-conductor and organic light emitting diodes) that may be configured to generate radiation in one or more of the infrared spectrum, ultraviolet spectrum, and various portions of the visible spectrum (generally including radiation wavelengths from approximately 400 nanometers to approximately 700 nanometers). Some examples of LEDs include, but are not limited to, various types of infrared LEDs, ultraviolet LEDs, red LEDs, blue LEDs, green LEDs, yellow LEDs, amber LEDs, orange LEDs, and white LEDs (discussed further below). It also should be appreciated that LEDs may be configured and/or controlled to generate radiation having various bandwidths (e.g., full widths at half maximum, or FWHM) for a given spectrum (e.g., narrow bandwidth, broad bandwidth), and a variety of dominant wavelengths within a given general color categorization.

For example, one implementation of an LED configured to generate essentially white light (e.g., a white LED) may include a number of dies which respectively emit different spectra of electroluminescence that, in combination, mix to form essentially white light. In addition, each of the dies may be individually addressable by a controller to turn on or off, or to emit light at particular intensities to generate a variety of colors or color temperatures when used singly or in combination with the other dies. In another implementation, a white light LED may be associated with a phosphor material that converts electroluminescence having a first spectrum to a different second spectrum. In one example of this implementation, electroluminescence having a relatively short wavelength and narrow bandwidth spectrum “pumps” the phosphor material, which in turn radiates longer wavelength radiation having a somewhat broader spectrum.

It should also be understood that the term LED does not limit the physical and/or electrical package type of an LED. For example, as discussed above, an LED may refer to a single light emitting device having multiple dies that are configured to respectively emit different spectra of radiation (e.g., that may or may not be individually controllable). Also, an LED may be associated with a phosphor that is considered as an integral part of the LED (e.g., some types of white LEDs). In general, the term LED may refer to packaged LEDs, non-packaged LEDs, surface mount LEDs, chip-on-board LEDs, T-package mount LEDs, radial package LEDs, power package LEDs, LEDs including some type of encasement and/or optical element (e.g., a diffusing lens), etc.

A given LED may be configured to generate electromagnetic radiation within the visible spectrum, outside the visible spectrum, or a combination of both. Hence, the terms “light” and “radiation” are used interchangeably herein. Additionally, a LED may include as an integral component one or more filters (e.g., color filters), lenses, or other optical elements. Also, it should be understood that light sources may be configured for a variety of applications, including, but not limited to, indication and/or illumination. LED devices described herein can be particularly configured to generate radiation having a sufficient intensity to effectively illuminate an interior or exterior space. In this context, “sufficient intensity” refers to sufficient radiant power in the visible spectrum generated in the space or environment (the unit “lumens” often is employed to represent the total light output from a light source in all directions, in terms of radiant power or “luminous flux”) to provide ambient illumination (i.e., light that may be perceived indirectly and that may be, for example, reflected off of one or more of a variety of intervening surfaces before being perceived in whole or in part).

The term “spectrum” should be understood to refer to any one or more frequencies (or wavelengths) of radiation produced by one or more light sources. Accordingly, the term “spectrum” refers to frequencies (or wavelengths) not only in the visible range, but also frequencies (or wavelengths) in the infrared, ultraviolet, and other areas of the overall electromagnetic spectrum. Also, a given spectrum may have a relatively narrow bandwidth (e.g., a FWHM having essentially few frequency or wavelength components) or a relatively wide bandwidth (several frequency or wavelength components having various relative strengths). It should also be appreciated that a given spectrum may be the result of a mixing of two or more other spectra (e.g., mixing radiation respectively emitted from multiple light sources).

For purposes of this disclosure, the term “color” is used interchangeably with the term “spectrum.” However, the term “color” generally is used to refer primarily to a property of radiation that is perceivable by an observer (although this usage is not intended to limit the scope of this term). Accordingly, the terms “different colors” implicitly refer to multiple spectra having different wavelength components and/or bandwidths. It also should be appreciated that the term “color” may be used in connection with both white and non-white light.

The term “color temperature” generally is used herein in connection with white light, although this usage is not intended to limit the scope of this term. Color temperature essentially refers to a particular color content or shade (e.g., reddish, bluish) of white light. The color temperature of a given radiation sample conventionally is characterized according to the temperature in degrees Kelvin (K) of a black body radiator that radiates essentially the same spectrum as the radiation sample in question. Black body radiator color temperatures generally fall within a range of from approximately 700 degrees K (typically considered the first visible to the human eye) to over 10,000 degrees K; white light generally is perceived at color temperatures above 1500-2000 degrees K.

Lower color temperatures generally indicate white light having a more significant red component or a “warmer feel,” while higher color temperatures generally indicate white light having a more significant blue component or a “cooler feel.” By way of example, fire has a color temperature of approximately 1,800 degrees K, a conventional incandescent bulb has a color temperature of approximately 2848 degrees K, early morning daylight has a color temperature of approximately 3,000 degrees K, and overcast midday skies have a color temperature of approximately 10,000 degrees K. A color image viewed under white light having a color temperature of approximately 3,000 degree K has a relatively reddish tone, whereas the same color image viewed under white light having a color temperature of approximately 10,000 degrees K has a relatively bluish tone.

Additionally, lighting devices described herein optionally may be associated with (e.g., include, be coupled to and/or packaged together with) various other components (e.g., control circuitry) relating to the operation of the LED(s). A “multi-channel” lighting device refers to or includes at least two LEDs configured to respectively generate different spectrums of radiation, wherein each different source spectrum may be referred to as a “channel” of the multi-channel lighting unit.

In accordance with exemplary embodiments, each of the lighting devices described herein can be controlled by a controller. The term “controller” is used herein generally to describe various apparatus relating to the operation of one or more lighting devices. A controller can be implemented in numerous ways (e.g., such as with dedicated hardware) to perform various functions discussed herein. A “processor” is one example of a controller which employs one or more microprocessors that may be programmed using software (e.g., microcode) to perform various functions discussed herein. A controller may be implemented with or without employing a processor, and also may be implemented as a combination of dedicated hardware to perform some functions and a processor (e.g., one or more programmed microprocessors and associated circuitry) to perform other functions. Examples of controller components that may be employed in various embodiments of the present disclosure include, but are not limited to, conventional microprocessors, application specific integrated circuits (ASICs), and field-programmable gate arrays (FPGAs).

In various implementations, a processor or controller may be associated with one or more storage media (generically referred to herein as “memory,” e.g., solid-state drives (SSDs) volatile and non-volatile computer memory such as RAM, PROM, EPROM, and EEPROM, floppy disks, compact disks, optical disks, magnetic tape, etc.). In some implementations, the storage media may be encoded with one or more programs that, when executed on one or more processors and/or controllers, perform at least some of the functions discussed herein. Various storage media may be fixed within a processor or controller or may be transportable, such that the one or more programs stored thereon can be loaded into a processor or controller so as to implement various aspects of the present invention discussed herein. The terms “program” or “computer program” are used herein in a generic sense to refer to any type of computer code (e.g., software or microcode) that can be employed to program one or more processors or controllers.

The term “addressable” is used herein to refer to a device (e.g., an LED in general, or a lighting device, a controller or processor associated with one or more LEDs or lighting devices, other non-lighting related devices, etc.) that is configured to receive information (e.g., data) intended for multiple devices, including itself, and to selectively respond to particular information intended for it. The term “addressable” often is used in connection with a networked environment (or a “network,” discussed further below), in which multiple devices are coupled together via some communications medium or media.

In one network implementation, one or more devices coupled to a network may serve as a controller for one or more other devices coupled to the network (e.g., in a master/slave relationship). In another implementation, a networked environment may include one or more dedicated controllers that are configured to control one or more of the devices coupled to the network. Generally, multiple devices coupled to the network each may have access to data that is present on the communications medium or media; however, a given device may be “addressable” in that it is configured to selectively exchange data with (i.e., receive data from and/or transmit data to) the network, based, for example, on one or more particular identifiers (e.g., “addresses”) assigned to it.

The term “network” as used herein refers to any interconnection of two or more devices (including controllers or processors) that facilitates the transport of information (e.g., for device control, data storage, data exchange, etc.) between any two or more devices and/or among multiple devices coupled to the network. As should be readily appreciated, various implementations of networks suitable for interconnecting multiple devices may include any of a variety of network topologies and employ any of a variety of communication protocols. Additionally, in various networks according to the present disclosure, any one connection between two devices may represent a dedicated connection between the two systems, or alternatively a non-dedicated connection. In addition to carrying information intended for the two devices, such a non-dedicated connection may carry information not necessarily intended for either of the two devices (e.g., an open network connection). Furthermore, it should be readily appreciated that various networks of devices as discussed herein may employ one or more wireless, wire/cable, and/or fiber optic links to facilitate information transport throughout the network.

In accordance with exemplary embodiments, lighting devices described herein can be controlled via a user interface. The term “user interface” as used herein refers to an interface between a human user or operator and one or more devices that enables communication between the user and the device(s). Examples of user interfaces that may be employed in various implementations of the present disclosure include, but are not limited to, switches, potentiometers, buttons, dials, sliders, a mouse, keyboard, keypad, various types of game controllers (e.g., joysticks), track balls, display screens, various types of graphical user interfaces (GUIs), touch screens, microphones and other types of sensors that may receive some form of human-generated stimulus and generate a signal in response thereto.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention.

FIG. 1 illustrates a side view of a lighting device 100 including an LED spinal component and a circuit board strip in accordance with exemplary embodiments;

FIG. 2 illustrates a top view of a lighting device 100 including an LED spinal component and a circuit board strip in accordance with exemplary embodiments;

FIG. 3 illustrates an LED strip lighting device 300 comprising examples of LED spinal components of FIGS. 1-2;

FIG. 4 illustrates a close-up view of a subset of LED spinal components of the LED strip lighting device 300;

FIG. 5 illustrates an LED strip lighting device 500 in accordance with alternative exemplary embodiments;

FIG. 6 illustrates a flexed LED strip lighting device 500 in accordance with exemplary embodiments; and

FIG. 7 is a high-level flow diagram for a method 700 for producing a lighting device in accordance with exemplary embodiments.

### DETAILED DESCRIPTION

Exemplary embodiments of the present application are directed to flexible lighting strips that can provide lateral light emitting effects. In particular, embodiments described herein can be configured to generate a high intensity wall washing-effect, while at the same time provide additional space for electrical components without affecting the flexibility of the underlying strip. In addition, the embodiments can provide enhanced structural integrity for any optics applied to the device with a reduced risk of delamination due to flexing of the strip.

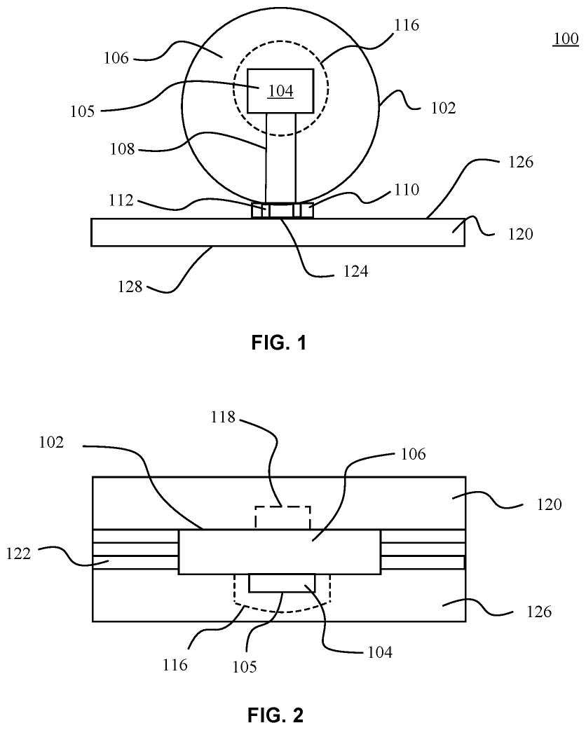

Referring now to FIGS. 1 and 2, a lighting device 100 in accordance with an exemplary embodiment of the present application is illustrated. FIG. 1 provides a side view of the device 100, while FIG. 2 provides a top view of the lighting device 100. As illustrated in FIGS. 1 and 2, the lighting device 100 includes an LED spinal component 102 and a circuit board strip 120. The circuit board strip 120 includes conductors 122 disposed on a top surface 126 of the strip 120, and can be composed of any material used in LED tapes. For example, the strip 120 can be a flex printed circuit board (PCB) or printed circuit board assembly (PCBA) composed of polyamide with metallic tracers, e.g., copper, as the conductors 122, which can be coupled to a power supply to power the lighting device 100. In preferred embodiments, the underside 128 of the strip can be configured to include attachment means for mounting to a surface. For example, the underside 128 can include an adhesive or a mechanical clip that attaches to a surface, such as a wall, floor or ceiling. In particular, the flexibility of the strip enables the strip to attach to and trace a non-linear surface, e.g. around corners. The LED spinal component 102 can include an LED 104 disposed on a circuit board 106, which can be a rigid PCB or PCBA that includes conductors 108 composed of, for example, copper, that are coupled to and power the LED 104. As understood in the art, a rigid PCB or PCBA can be a laminated structure with conductive and insulating layers composed of resins (e.g., epoxy) and fiber (e.g., glass) fillers, that are more rigid/less flexible that the strip 120. Here, the LED 104 is mounted on the strip 120 so that a primary light emitting surface 105 of the LED spinal component 102 is at a perpendicular or oblique angle to a portion 124 of the surface of the strip at which the LED spinal component is attached. The surface 105 is disposed preferably between 800-1000 with respect to the surface portion 124 of the strip 120, and most preferably the surface 105 is perpendicular to the surface portion 124 of the strip 120. However, the LED spinal component 102 can be attached to the strip 120 so that the surface 105 is disposed at any oblique angle with respect to the surface portion 124 of the strip 120. In accordance with one embodiment, the LED spinal component 102 is soldered to the strip 120 in a manner that is similar to how an LED is soldered to a flexible substrate in a traditional LED tape, as understood by those of ordinary skill in the art. Here, the solder 110 provides a coupling 112 between the conductors 108 of the LED spinal component 102 and the conductors 122 of the strip 120.

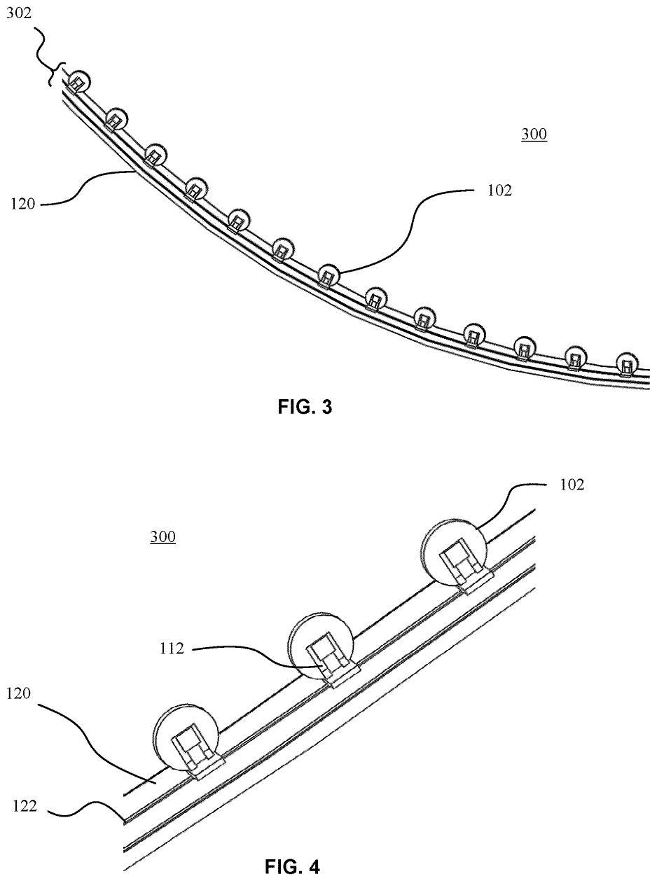

Configuring the lighting device so that the light emitting surface 105 is at a perpendicular or oblique angle with respect to the surface 124 of the strip 120 as described above enables a full wall washing lighting effect that can provide a significant visual improvement over side emitting LEDs or devices that rely on a reflector to emit light in a lateral direction. In addition, the configuration permits the addition of optional electrical components 118 on the back side of the circuit board 106 that could not be implemented with a traditional LED tape design. Some examples of electrical components include, but are not limited to a buck/boost (DC-DC) circuit, sensors, RGBW (red, green, blue and white) control, microcontrollers, etc. Further, one or more optical elements 116 can be included over the LED 104 to provide an optical effect from light emitted by the LED 104. Optical elements can include reflectors with or without lenses, clear total internal reflection (TIR) optics and/or refractive optics. They can either be discreet optics controlling each LED individually, or if extruded from a flexible material could be an extruded profile that bends with the rest of the assembly. Here, due to the relatively higher degree of rigidity of the circuit board 106 as compared to the flexible strip 120, the structural integrity of the optical element 116 is improved over the use of traditional LED tape. As indicated above, the circuit board 106 can be a rigid PCB or PCBA, while the strip 120 can be a flex PCB or PCBA, where the material composing the strip 120 is more flexible than the circuit board 106. For example, the flexibility of the material composing the flex PCB or PCBA is such that a first end of a six-inch (or 15.24 cm) long strip of this material is bendable 360 degrees back onto a second, opposing end of the six-inch long strip without incurring breakage. In turn, the material composing the rigid PCB or PCBA is such that a first end of a six-inch long piece of the rigid PCB or PCBA is unbendable 360 degrees back onto a second, opposing end of the six-inch long piece without incurring breakage. Indeed, the rigid PCB or PCBA, which can be composed of, for example, FR4, would break at a less than a 90 degree bend. However, the rigid PCB or PCBA requires a significantly higher load to bend even a few degrees when compared to the flex PCB or PCBA. The combination of the circuit board 106 and the strip 120 in the configurations described herein ensures that the risk of delamination and/or breakage of the optical element 116 is significantly reduced when the strip 120 is flexed, as illustrated in FIGS. 3 and 4.

FIG. 3 illustrates an LED strip lighting device 300 which includes a plurality 302 of LED spinal components 102 attached to the circuit board strip 120 in the manner discussed above with respect to FIGS. 1 and 2. Here, the strip lighting device 300 can be attached to and trace a non-linear surface as discussed above without stress on any optical elements 116 disposed on LEDs 104 of the plurality 302 of spinal components. As shown in FIG. 3, due to the configuration of the spinal components 102, which are mounted so that the primary light emitting surfaces 105 are at a perpendicular or oblique relative to the surface portions 124 of the strip 120 and comprise relatively rigid circuit boards, flexing of the strip 120 does not place stress on any optical element 116, as the spinal components 102, which are free standing with respect to each other LED spinal component 102 of the plurality 302, simply move toward or away from each other during flexing, similar to vertebrae of a spinal column. Thus, in this way, for example, the configuration of the spinal components 102 on the strip 120 provide the optical elements 116 with a degree of structural integrity that is greater than a structural integrity of the optical element 116 if disposed on the circuit board strip 120 as in traditional LED tape, which is susceptible to delamination of optical components during flexing. FIG. 4 provides a magnified view of a portion of the plurality 302 of LED spinal components 102 from a back side of the components 102.

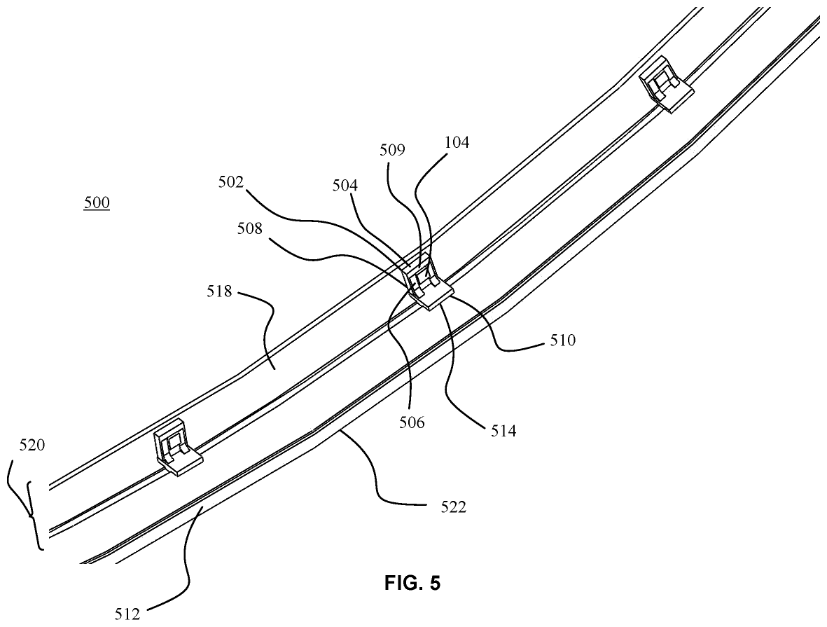

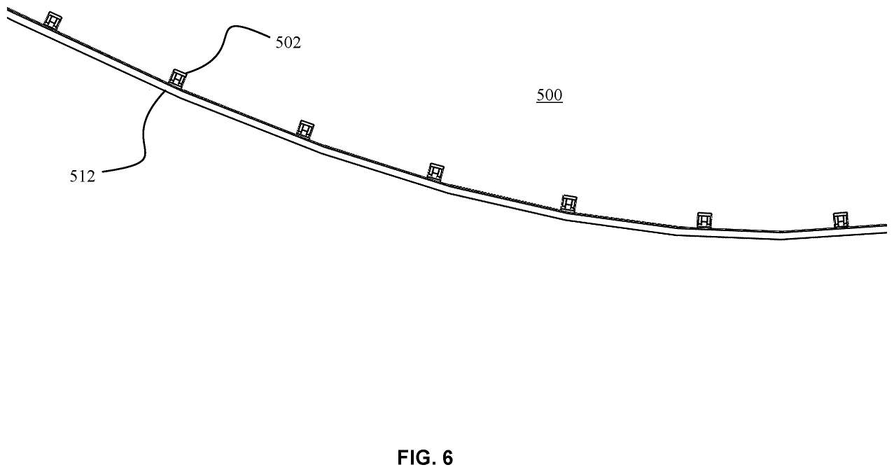

FIG. 5 illustrates another embodiment of an LED strip lighting device 500, which comprises a circuit board strip 512 and an LED spinal component 502. The LED spinal component 502 comprises an LED 104 mounted on a circuit board 506, which in turn is mounted on the surface 509 of a coupler 504. Here, as opposed to employing soldering or other similar mounting methods, the LEDs 104 and circuit board 506 are mounted to the circuit board strip 120 via a coupler 504, which can be attached to the circuit board strip 512 through mechanical means, such as, for example, a snap-on coupler which includes a protrusion on the coupler 502 for insertion in a corresponding groove in provided on the strip 512. Here, the bottom surface 510 of the coupler 504 can be mounted on a portion 514 of the top surface of the strip 512 so that electrical conductors in the top surface 514 are in contact with electrical conductors running through the coupler 504 to the LED 104 to power the LED 104. In addition, the lighting device 500 further includes a second strip 518 that is attached, via, for example an adhesive or through mechanical means, to the back surface 508 of the coupler 504. The second strip 518 can be a reflector for purposes of enhancing the lateral light emission from the LEDs 504. The surfaces 508 and 509 of the coupler 504 are at a perpendicular or oblique angle to the surface portion 514 of the strip 512 and to the bottom surface 510 of the coupler 504, so that the primary light emitting surface of the LED 104 is at the same perpendicular or oblique angle to the portion 514 of the surface of the strip 512 at which the LED spinal component 502 is attached. As indicated above, the circuit board 506 is disposed on the surface 509 of the coupler 504 and the surface portion 514 of the strip is disposed on the surface 510 of the coupler 504.

Both the coupler 504 and the circuit board 506 can be more rigid/less flexible than the material composing the strip 512 and the second strip 518. For example, the circuit board 506 can be a rigid circuit board, discussed above, while the strip 512 can be a flex circuit board, discussed above. Both strips 512 and 518 are flexible to enable attachment to and tracing along a non-linear surface. Similar to the embodiments described with respect to FIGS. 1 and 2, the underside 522 of the strip 512 can be configured to include attachment means for mounting to the surface, such as, for example, an adhesive or a mechanical clip. In addition, second strip 518 is perpendicularly or obliquely attached to first strip 512 due to the structural configuration of the coupler 504.

As illustrated in FIGS. 5-6, the LED strip lighting device 500 includes a plurality 520 of LED spinal components 502. Similar to the embodiments described with respect to FIGS. 1 and 2, due to the configuration of the spinal components 502 and the flexibility of the strip 518, flexing of the strip 512 does not place significant stress on any optical element applied to the LED 104 of the spinal components 502, thereby substantially reducing the risk of delamination and/or breakage of the optical elements and providing enhanced structural integrity of the optical elements.

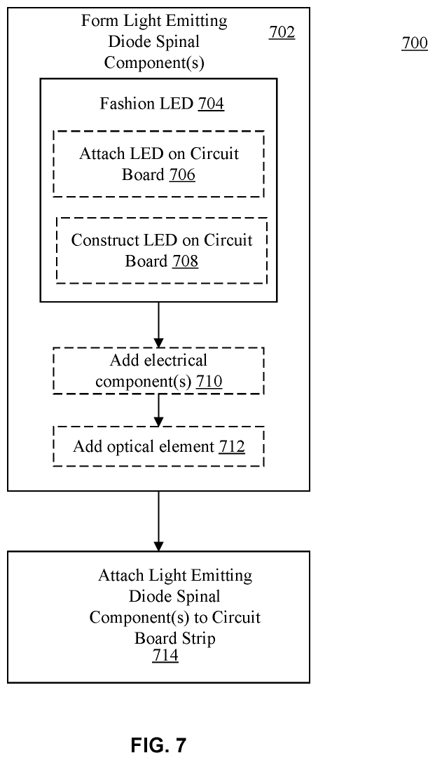

With reference now to FIG. 7, a high-level flow diagram for a method 700 for producing a lighting device is illustrated. The method 700 and optional variations of the method 700 can be employed to produce the lighting devices 100, 300 or 500 described above. At step 702, an LED spinal component 102 or 502 can be formed. For example, at step 704, the LED 104 can be fashioned at step 704 by attaching, at step 706, a completed LED on a circuit board 106 or 506, or by constructing, at step 708, an LED 104 on the circuit board 106 or 506. For example, cladding and active layers of the LED can be deposited on the circuit board 106 or 506. Step 702 can be repeated to form a plurality 302 or 520 of LED spinal components 102 or 502. Preferably, step 704 is performed, wherein LEDs 104 are attached/soldered to a rigid PCBA using standard practices and cut in discrete elements comprising one or more LEDs forming LED element 104. At optional step 710, electrical components 118 can be added to the back side of LED spinal components 102 or 502. In addition, at optional step 712, optical elements 116 can be added to the LED element 104 of LED spinal components 102 or 502. At step 714, the LED spinal components 102 or 502 can be attached to the circuit board strip 120 or 512. For example, as discussed above with respect to FIGS. 1-4, the LED spinal components 102 can be soldered to the circuit board strip 120. Preferably, discrete elements of the rigid PCBA cut at step 704 are soldered onto a flexible PCBA at the same locations and in a similar manner as in a traditional LED tape. Alternatively, at step 714, the LED spinal components 502 can be attached to the circuit board strip 512 using a coupler 504, as discussed above with respect to FIGS. 5-6.

While several inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,”“containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A lighting device comprising:
a first light emitting diode (LED) spinal component including a first an-LED disposed on a first circuit board including first electrical conductors coupled to said LED; and
a circuit board strip including second electrical conductors coupled to said first electrical conductors, wherein the material composing said strip is more flexible than said first circuit board, and wherein said first LED spinal component is attached at a portion of a surface of said strip such that a primary light emitting surface of the first LED spinal component is at a perpendicular or oblique angle to said portion of said surface of said strip at which said first LED spinal component is attached, wherein said first LED spinal component comprises a coupler having a first surface and a second surface that is at a perpendicular or oblique angle to the first surface, wherein the first circuit board is disposed on the first surface, and said portion of said surface of said strip is disposed on said second surface, wherein a discrete optical element is disposed on said first LED spinal component and is configured to form an optical effect from light emitted by said first LED; and
a second LED spinal component including a second LED disposed on a second circuit board and a second discrete optical element disposed on said second spinal component and is configured to form an optical effect from light emitted by said second LED, and wherein said second LED spinal component is attached to said strip.

2. The lighting device of claim 1, wherein the flexibility of the material composing said strip is such that a first end of a six-inch (15.24 cm) long strip of said material is bendable 360 degrees back onto a second, opposing end of said six-inch long strip without incurring breakage, while the material composing said first circuit board is such that a first end of a six-inch (15.24 cm) long piece of said material composing said first circuit board is unbendable 360 degrees back onto a second, opposing end of said six-inch long piece.

3. The lighting device of claim 1, wherein the first discrete optical element is different than the second discrete optical element.

4. The lighting device of claim 3, wherein said first circuit board provides said optical element with a degree of structural integrity that is greater than a structural integrity of said optical element if disposed on said circuit board strip.

5. The lighting device of claim 1, wherein the first circuit board is a rigid printed circuit board (PCB) and the strip is a flex PCB.

6. The lighting device of claim 1, wherein said first LED spinal component and said second LED spinal component are included in a plurality of LED spinal components attached to respective portions of said surface of said strip such that primary light emitting surfaces of the plurality of LED spinal components are at a perpendicular or oblique angle to the respective portions of said surface of said strip.

7. The lighting device of claim 6, wherein each LED spinal component of said plurality is free standing with respect to each other LED spinal component of said plurality.

8. The lighting device of claim 6, wherein said strip is a first strip, wherein said lighting device further comprises a second strip that is perpendicularly or obliquely attached to said first strip and wherein said plurality of LED spinal components are disposed on the second strip.

9. The lighting device of claim 8, wherein the material composing said second strip is more flexible than said first circuit board.

10. The lighting device of claim 8, wherein said second strip is a reflector.

11. A method for producing a lighting device comprising:
forming first light emitting diode (LED) spinal component by fashioning an first LED on a first circuit board such that first electrical conductors of said first circuit board are coupled to said first LED;
attaching said first LED spinal component to a circuit board strip such that second electrical conductors of said strip are coupled to said first electrical conductors, wherein the material composing said strip is more flexible than said first circuit board and wherein said first LED spinal component is attached at a portion of a surface of said strip such that a primary light emitting surface of the first LED spinal component is at a perpendicular or oblique angle to said portion of said surface of said strip at which said first LED spinal component is attached, wherein said first LED spinal component comprises a coupler having a first surface and a second surface that is at a perpendicular or oblique angle to the first surface, wherein the first circuit board is disposed on the first surface, and said portion of said surface of said strip is disposed on said second surface, wherein a discrete optical element is disposed on said first LED spinal component and is configured to form an optical effect from light emitted by said first LED; and
a second LED spinal component including a second LED disposed on a second circuit board and a second discrete optical element disposed on said second spinal component and is configured to form an optical effect from light emitted by said second LED, and wherein said second LED spinal component is attached to said strip.

12. The method of claim 11, wherein said attaching comprises soldering said first LED spinal component to said surface of said strip.

13. The method of claim 11, wherein said fashioning comprises attaching said first LED on to said first circuit board.

14. The method of claim 11, wherein said fashioning comprises constructing said first LED on said first circuit board.
